(19) United States
(12) Patent Application Publication
(10) Pub. No.: US 2003/0184401 A1
(43) Pub. Date: Oct. 2, 2003

(54) Apparatus and method of generating oscillations

(76) Inventor: Eliav Zipper, Tel Aviv (IL)

Correspondence Address: EITAN, PEARL, LATZER & COHEN ZEDEK LLP, 10 ROCKEFELLER PLAZA, SUITE 1001, NEW YORK, NY, 10020, US

(21) Appl. No.: 10/109,009

(22) Filed: Mar. 29, 2002

(51) Int. Cl. H04B 1/00; H03L 5/00

(52) U.S. Cl. 331/182

(57) ABSTRACT

Briefly, in accordance with one embodiment of the invention, an oscillator with an automatic amplitude control loop is provided. The oscillator may include a pair of cross-coupled amplifying devices having at least two outputs. The first output may provide an oscillations and the second output may provide an amplitude detect signal.

### BACKGROUND

Oscillators may be used in many applications such as, for example, phase lock loop synthesizers, frequency sources, clocks, timers, processors, the baseband of transceivers of portable communication devices, and the like.

Types of oscillators that may be used in portable communication devices may include differential oscillators. Differential oscillators may provide a high frequency signal using a very low voltage source such as, for example a battery, and may include an automatic amplitude control loop to provide a high frequency signal with a constant amplitude level.

However, differential oscillators may generate phase noise and amplitude modulation (AM) noise that may have an impact on the overall performance of the oscillator. Furthermore, ground disturbance may affect the phase noise and the AM noise.

Thus, there is a continuing need for better ways to provide an oscillator that generates less noise.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a schematic representation of a portion of portable communication device according to an embodiment of the present invention; and

FIG. 2 is a schematic representation of a voltage-controlled oscillator having automatic amplitude control in accordance with an embodiment the present invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

It should be understood that embodiments of the present invention may be used in a variety of applications. For example, embodiments of oscillators according to the present invention may be used in various modules, circuits, integrated circuits, hybrids and the like. Types of oscillators that may be used with embodiments of the present invention may be voltage-controlled oscillators (VCO), ring oscillators, differential oscillators and the like. In addition, embodiments of the circuits and techniques disclosed herein may be used in many apparatuses such as phase lock loops (PLL) that may be used in synthesizers of a portable communication device, if desired.

Types of portable communication devices that may include oscillators according to embodiments of the present invention may be, by way of example only, cellular radiotelephone mobile stations, two-way radio mobile stations, and the like.

Types of cellular radiotelephone mobile stations intended to be within the scope of the present invention include, although not limited to, Code Division Multiple Access (CDMA) and wide band CDMA (W-CDMA), Global System for Mobile communication (GSM), Time Division Multiple Access (TDMA), Extended-TDMA (E-TDMA), General Packet Radio Service (GPRS), Extended GPRS, and the like.

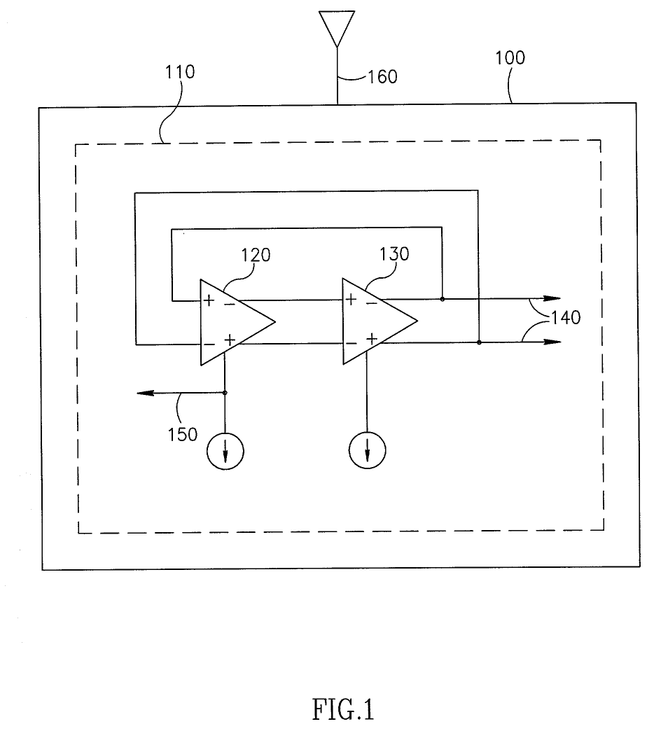

Turning first to FIG. 1, a block diagram of a portable communications device 100 according to an embodiment of the invention is shown. Although the scope of the present invention is in no way limited to this example, portable communication device 100 may include one or more oscillators according to embodiments of the present invention in various modules, circuits, integrated circuits, hybrids and the like. For example, an oscillator 110 may include a differential pair of cross-coupled amplifying devices 120 and 130. For example, the differential pair of cross-coupled amplifying devices may be a pair of substantially similar, complementary amplifying devices that have a differential input and differential output. Furthermore, the term “cross-coupled” which is used with embodiments of the present invention may describe that the input of a first device of the pair may be connected to the output of the second device of the pair. In addition, the output of a first device of the pair may be connected to the input of the second device of the pair. Amplifying device 130 may have differential output 140 to provide oscillations and amplifying device 120 may have an output 150 to provide a signal which may be substantially proportional to an amplitude level of the oscillations.

Although the scope of the present invention is not limited in this respect, in an alternative embodiment of the present invention, a combiner 170 may combine differential output 140 to provide an output relative to a ground potential, if desired.

Although the scope of the present invention is not limited in this respect, portable communication device 100 may include an antenna 160, for example a dipole antenna, a shot antenna, a dual antenna, an omni-directional antenna, a loop antenna or the like, to transmit and receive a radio frequency (RF) signal.

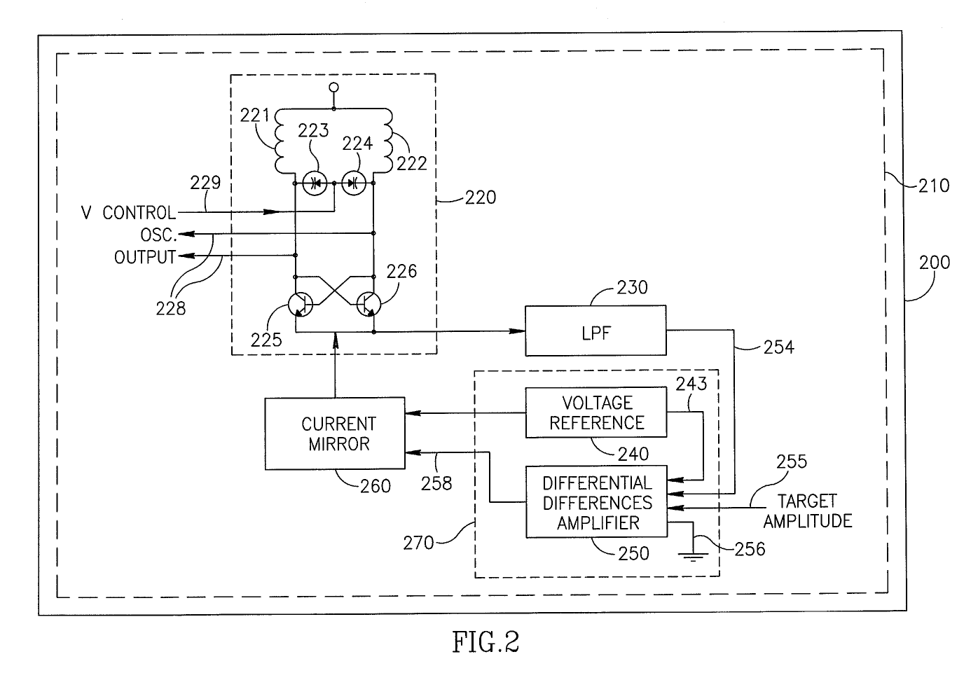

Turning to FIG. 2, an apparatus 200, which includes an oscillator 210 according to an embodiment of the present invention, is shown. Although it should be understood that the scope and application of the present invention is in no way limited to these examples, apparatus 200 may be a phase lock loop, a frequency generator, a clock of digital components, a reference oscillator of a receiver and transmitter, a crystal oscillator, or the like. In addition, some embodiments of the present invention may be directed to oscillators comprising a differential pair of cross-coupled amplifying device having at least two outputs. Embodiments directed to this architecture may be, for example, ring oscillator 110 of FIG. 1 and VCO 220 of FIG. 2

Although it should be understood that the scope and application of the present invention is in no way limited to this example, oscillator 210 may include a voltage controlled oscillation (VCO) generator 220, a low pass filter (LPF) 230, a voltage reference 240, a differential difference amplifier 250 and a current mirror 260. For example, VCO generator 220 may include coils 221 and 222, varactors 223 and 224 and a pair of cross-coupled transistors 225 and 226.

In operation, coils 221, 222 and varactors 223, 224, respectively may be in resonance which may generate oscillations. The frequency of the oscillations may be determined by a control voltage (V control) 229. The control voltage may change the capacitance of varactors 223 and 224 by providing different levels of voltage to the varactors, thus changing the resonance frequency of coils 221, 222 and varactors 223, 224. In addition, cross-coupled transistors 225 and 226 may be designed to provide amplification to initiate and maintain the oscillations. Furthermore, in accordance with one embodiment of the present invention, transistors 225 and 226 may be bipolar junction transistors (BJT's).

Although the scope of the present invention is not limited in this respect, cross-coupled transistors 225 and 226 may be used for at least two purposes. The first purpose may be to provide oscillations through a differential output 228 of the differential pair cross-coupled transistors 225 and 226, and the second purpose may be to provide an amplitude detect signal of the oscillations through an output 227. In accordance with one embodiment of the present invention, differential pair cross-coupled transistors 225 and 226 may rectify the oscillations to detect their amplitude. For example, transistor 225 may provide a first half-wave rectification of the oscillations, and transistor 226 may provide a second half-wave rectification of the oscillations. The combination of the two half-rectified signals may be provided as output 227. In addition, LPF 230 may filter the low frequencies of the rectified signal to provide a direct current (DC) voltage potential. The DC potential may be proportional to the amplitude level of the oscillations, for example, an average amplitude level of the oscillations. Furthermore, current mirror 260 may replicate the current of differential pair cross-coupled transistors 225 and 226 bases by providing a substantially equal current to output 227. Current mirror 260 may provide a current to stabilize the amplitude of the oscillations and may filter the AM noise of oscillator 210.

Although the scope of the present invention is not limited in this respect, an automatic amplitude control loop 270 which may include voltage reference 240 and differential difference amplifier 250 may be provided. Automatic amplitude control loop 270 may control the amplitude level of the oscillations according to a target amplitude 255. Furthermore, the control loop may vary the current of current mirror 260 according to the target amplitude 255.

Although the scope of the present invention is not limited in this respect, differential difference amplifier 250 may provide a control signal to current mirror 260. Differential difference amplifier 250 may receive the average amplitude output level of the oscillations 254 and a voltage potential 243 from voltage reference 240 to provide a first difference. In addition, differential difference amplifier 250 may receive target amplitude level 255 and a voltage reference, for example, a ground potential 256, to provide a second difference. Differential difference amplifier 250 may output a control signal 258. Control signal 258 may be a combined signal that comprises the difference of the first difference from the second difference. For example, if the target amplitude level 255 is substantially equal to the average amplitude level of the oscillations, then the control signal 258 may be zero, otherwise the control signal 258 may control current mirror 260 to vary the amplitude of the oscillations to be substantially equal to target amplitude 255. Furthermore, voltage reference 240 may provide a voltage reference that is substantially equal to the offset voltage of differential pair cross-coupled transistors 225 and 226.

Although the scope of the present invention is not limited by the inclusion or exclusion of such components, in alternative embodiments of the present invention transistors 225, 226 may be replaced with field-effect transistors (FET), differential amplifiers and the like.

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

1. An oscillator comprising:
a differential pair of cross-coupled amplifying devices having a first output to provide oscillations and a second output to provide an amplitude of the oscillations.

2. The oscillator of claim 1, further comprising:
a low pass filter coupled to the second output; and
a current mirror coupled to the second output.

3. The oscillator of claim 2, further comprising:
a differential differences amplifier to control the amplitude level of the oscillations according to a combined signal that comprises a difference of a first voltage reference signal and the amplitude level of the oscillations and a difference of a target amplitude level and a second voltage reference signal.

4. The oscillator of claim 1, further comprising:
a voltage input to control a frequency of oscillations of the oscillator.

5. The oscillator of claim 1, wherein the amplifying devices comprise bipolar junction transistors.

6. The oscillator of claim 1, wherein the amplifying devices comprise field-effect transistors.

7. A portable communication device comprising:
an oscillator having a differential pair of cross-coupled amplifying devices having a first output to provide oscillations and a second output to provide an amplitude detect signal of the oscillations; and
a dipole antenna.

8. The portable communication device of claim 7, wherein the oscillator further comprises:
a current mirror operably coupled to the second output; and
a low pass filter to filter the amplitude of the second output.

9. The portable communication device of claim 8, wherein the oscillator further comprises:
a differential differences amplifier to control the amplitude level of the oscillations according to a combined signal which comprises at least one of a difference of a first voltage reference signal and the amplitude level of the oscillations, and a difference of a target amplitude level and a second voltage reference signal.

10. The portable communication device of claim 9, wherein the amplifying devices comprise bipolar junction transistors.

11. The portable communication device of claim 10, wherein the amplifying devices comprise field-effect transistors.

12. An apparatus comprising:
an oscillator having a pair of cross-coupled amplifying devices having a first output to provide oscillations and a second output to provide an amplitude of the oscillations; and
an automatic amplitude control loop to control the amplitude level of the oscillations according to a target amplitude level.

13. The apparatus of claim 12, wherein the oscillator further comprises:
a current mirror coupled to the second output; and
a low pass filter coupled to the second output.

14. The apparatus of claim 13, wherein the oscillator further comprises:
a differential differences amplifier to control the amplitude level of the oscillations according to a combined signal which comprises an at least one of a difference of a first voltage reference signal and the amplitude level of the oscillations, and a difference of the target amplitude level and a second voltage reference signal.

15. The apparatus of claim 12, wherein the amplifying devices comprise bipolar junction transistors.

16. The apparatus of claim 12, wherein the amplifying devices comprise field-effect transistors.

17. A method comprising:
detecting an amplitude of oscillations with a differential pair of cross-coupled amplifying devices which are controlling the generation of the oscillations.

18. The method of claim 17, further comprising:
providing a voltage potential to control a frequency of the oscillations.

19. The method of claim 18, further comprising:
generating a combined signal which is a difference of a first difference of a first reference voltage and an amplitude of oscillations, and a second difference of a target amplitude of the oscillations and a first reference voltage; and
controlling the amplitude of the oscillations according to the combined signal.

20. The method of claim 18, further comprising:
stabilizing the amplitude of the oscillations; and
filtering an amplitude modulation.
